(19) United States
(12) Patent Application Publication
(10) Pub. No.: US 2023/0058638 A1
(43) Pub. Date: Feb. 23, 2023

(54) SOLDER CREEP LIMITING RIGID SPACER FOR STACKED DIE C4 PACKAGING

(71) Applicant: International Business Machines Corporation, Armonk, NY (US)

(72) Inventors: David Abraham, Croton, NY (US); Gerard McVicker, Stormville, NY (US); Sri M. Sri-Jayantha, Ossining, NY (US); Vijayeshwar Das Khanna, Milwood, NY (US); Kathryn Jessica Pooley, Croton on Hudson, NY (US); Ricardo Alves Donaton, Cortlandt Manor, NY (US)

(21) Appl. No.: 17/445,254

(22) Filed: Aug. 17, 2021

(51) Int. Cl. H01L 23/00

(52) U.S. Cl. CPC H01L 24/81; H01L 24/16; H01L 24/11; H01L 2924/384; H01L 2224/10135; H01L 2224/10125; H01L 2224/16147; H01L 2224/11015; H01L 2224/81208; H01L 2224/81139; H01L 25/0657

(57) ABSTRACT

A die stack that includes a first chip die, a second chip die connected to the first chip die by one or more controlled collapse chip connection (“C4”) solder bump bonds, and a spacer die interposed between the first and second chip dies. The spacer die includes through holes for the one or more C4 solder bumps, and has a thickness such that when the first and second chip dies are compressed into contact with the spacer die, the spacer die thickness is a minimum defined spacing between the first and second chip dies, and the spacer die operates as a hard stop against compression of the die stack after the first and second chip dies are compressed into contact with the spacer die.

### RESEARCH OR DEVELOPMENT

This invention was made with U.S. Government support. The U.S. Government has certain rights in this invention.

### BACKGROUND

The present invention relates generally to the field of chip packaging, and more particularly to preserving chip integrity in packaging using controlled collapse chip connection (“C4”) bump bonding.

Silicon chips are built on silicon wafers and diced into chips. Often, a circuit is formed by interconnecting two or more chips. A common interconnection technique is the so-called flip chip or area array technique, also known as controlled collapse chip connection, or simply C4. For flip chips, a common technique is for an array of solder bump interconnects to be formed on bonding pads of a wafer before the wafer is diced into discrete first dies. Second dies with corresponding bonding pads are then oriented and aligned with the bumps and the first and second dies are joined together at the bumps using techniques that include one or more of solder reflow processes, cold-welding techniques, and other methods that are suitable to the fabrication, materials, the anticipated operating environment of the circuit, and other design and field-of-use considerations.

### BRIEF SUMMARY

One embodiment of the invention is directed to a die stack that includes a first chip die, a second chip die connected to the first chip die by one or more controlled collapse chip connection (“C4”) solder bump bonds, and a spacer die interposed between the first and second chip dies, wherein the spacer die includes through holes for the one or more C4 solder bumps, the spacer die has a thickness such that when the first and second chip dies are compressed into contact with the spacer die, the spacer die thickness has a minimum defined spacing between the first and second chip dies, and the spacer die operates as a hard stop against compression of the die stack after the first and second chip dies are compressed into contact with the spacer die.

In one aspect, the die stack includes an alignment hole through the spacer die that engages a corresponding alignment pin on one of the first chip die or second chip die, or engages alignment pins on both of the first chip die and the second die. In another aspect, an alignment pin on the spacer die engages a corresponding alignment hole on one of the first or second chip dies. In another aspect, an alignment hole through the spacer die engages a corresponding alignment pin on one of the first chip die or the second chip die, or engages alignment pins on both of the first and the second chip dies, and an alignment pin on the spacer die engages a corresponding alignment hole on one of the first chip die or the second chip die. Further, each arrangement may include two alignment pins and corresponding two alignment holes, wherein one of the alignment holes is dimensioned to fit its corresponding alignment pin to a close tolerance, and the other alignment hole is dimensioned with a sufficient oblong shape to allow for differential movement between the spacer die and one or both chip dies as a result of a difference between the coefficient of thermal expansion (CTE) of the spacer die and the chip dies.

In another aspect, the spacer die further includes one or both of a device through hole aligned with a device on one of the first chip die or second chip die, to reduce one or both of mechanical interference of the spacer die on the device or electrical effects of the spacer die on the device, and a device pocket etched into the spacer die that is aligned with a device on one of the first chip die or the second chip die, to reduce one or both of mechanical interference of the spacer die on the device or electrical effects of the spacer die on the device.

In another aspect, the spacer die further includes a channel etched into the spacer die that accommodates airflow through the die stack.

In another aspect, the spacer die comprises a lattice configuration.

In another aspect, one of the first chip die and the second chip die includes a pre-loaded connection pin contact pad aligned with a portion of the spacer die that provides compressive structural support to the chip die at the point where the pre-loaded connection pin contacts the connection pad.

In another aspect, the spacer die thickness allows for cold-weld compression bonding of the first chip die to the second chip die.

In another aspect, the diameter of each through hole is sufficiently larger than its corresponding uncompressed C4 bump such that an aligned spacer die may be placed on its associated chip die without touching any of the uncompressed C4 bumps.

In another aspect, the dimensions of each through hole are such that when the first chip die and second chip die are compressed into contact with the spacer die, the volume of the through hole is greater than the volume of its corresponding C4 bump such that the C4 bump does not overflow the through hole, and expansion of the C4 bump diameter does not cause electrical shorting between adjacent bumps or other connections.

In another aspect, the spacer die is comprised of the same materials as the substrate materials of the first and second chip dies. In other embodiments, the spacer die is comprised of a non-conducting material that acts as a hard stop against compression of the die stack after the first and second chip dies are compressed into contact with the spacer die, and with a coefficient of thermal expansion (CTE) similar enough to the CTE of the chip dies so as to eliminate damage to the C4 bumps caused by differential movement between the spacer die and one or both chip dies as a result of a difference between the CTEs of the spacer die and the chip dies. In certain embodiments, the spacer die is comprised a material selected from the group consisting of silicon, and glass.

In one embodiment, the invention is directed to a method of forming a die stack, that includes fabricating a first chip die, a second chip die, and a spacer die; placing the first chip die on a bonder base plate; placing the spacer die on top of the first chip die; placing the second chip die on a bonder pressure plate; and cold-welding the first chip die to the second chip die, at one or more controlled collapse chip connection (“C4”) solder bump bonds on one or both of the first chip die and the second chip die, by applying a compression force to the bonder compression plate. The spacer die includes through holes for the one or more C4 solder bumps, and has a thickness such that when the first and second chip dies are compressed into contact with the spacer die, the spacer die thickness is a minimum defined spacing between the first and second chip dies. The spacer die operates as a hard stop against compression of the die stack after the first and second chip dies are compressed into contact with the spacer die.

In another aspect, the first chip die, second chip die, and spacer die are fabricated such that an alignment hole through the spacer die engages a corresponding alignment pin on one of the first chip die or the second chip die, or engages alignment pins on both of the first chip die and the second die. In another aspect, an alignment pin on the spacer die engages a corresponding alignment hole on one of the first chip die or the second chip die. In another aspect, an alignment hole through the spacer die engages a corresponding alignment pin on one of the first chip die or the second chip die, or engages alignment pins on both of the first chip die and the second die, and an alignment pin on the spacer die that engages a corresponding alignment hole on one of the first chip die or the second chip die. Further, each arrangement may include two alignment pins and a corresponding two alignment holes, wherein one of the alignment holes is dimensioned to fit its corresponding alignment pin to a close tolerance, and the other alignment hole is dimensioned with a sufficient oblong shape to allow for differential movement between the spacer die and one or both chip dies caused by a difference between the coefficient of thermal expansion (CTE) of the spacer die and the chip dies.

In another aspect, the spacer die further includes one or more of a device through hole aligned with a device on one of the first or the second chip dies, so as to reduce one or both of mechanical interference of the spacer die on the device or electrical effects of the spacer die on the device, and a device pocket etched into the spacer die and aligned with a device on one of the first chip die or the second chip die, so as to reduce one or both of mechanical interference of the spacer die on the device or electrical effects of the spacer die on the device.

In another aspect, the spacer die includes a channel etched into the spacer die to accommodate airflow through the die stack.

In another aspect, the spacer includes a lattice configuration.

In another aspect, one of the first chip die and the second chip die includes a pre-loaded connection pin contact pad aligned with a portion of the spacer die that provides compressive structural support to the chip die at the point where the pre-loaded connection pin contacts the connection pad.

In another aspect, the spacer die thickness allows for cold-weld compression bonding of the first chip die to the second chip die.

In another aspect, the diameter of each through hole is sufficiently larger than its corresponding uncompressed C4 bump such that a properly aligned spacer die can be placed on its associated chip die without touching the uncompressed C4 bumps.

In another aspect, dimensions of each through hole are such that when the first and second chip dies are compressed into contact with the spacer die, the volume of the through hole is greater than the volume of its corresponding C4 bump such that the C4 bump does not overflow the through hole, and the expansion of the C4 bump diameter does not cause electrical shorting between adjacent bumps and other connections.

In another aspect, the spacer die is comprised of the same materials as the substrate materials of the first and second chip dies. In other embodiments, the spacer die is comprised of a non-conducting material that acts as a hard stop against compression of the die stack after the first and second chip dies are compressed into contact with the spacer die, and with a coefficient of thermal expansion (CTE) similar enough to the CTE of the chip dies so as to eliminate damage to the C4 bumps caused by a differential movement between the spacer die and one or both chip dies as a result of a difference between the CTEs of the spacer die and the chip dies. In certain embodiments, the spacer die is comprised a material selected from the group consisting of: silicon, and glass.

### BRIEF DESCRIPTION OF THE DRAWINGS

FIG. 1A is a cross-section of a prior art C4 die stack in a cold-weld compression process.

FIG. 1B is a cross-section of a prior art C4 die stack with multi-channel connector with spring-loaded connector pins.

FIG. 1C is a cross-section of a prior art die stack with pre-loaded heat sink.

FIG. 1D is a graph illustrating experimental results for C4 bump deformation over time as a function of a compression load.

FIG. 2 is a plan view of a spacer die, in accordance with an embodiment of the invention.

FIGS. 3A and 3B illustrate cross sections of a spacer die in a die stack before and after a cold-weld compression process, in accordance with an embodiment of the invention.

FIG. 4 illustrates a cross section of a die stack that includes a plurality of spacer dies, in accordance with an embodiment of the invention.

FIG. 5 illustrates a cross section of a die stack that includes a spacer die with an etched pocket over a device, in accordance with an embodiment of the invention.

FIG. 6A illustrates a cross section of a spacer die in a die stack in which a pre-loaded connection pin contacts a connection pad on a thin die and causes a deformation to the thin die and a bump beneath the thin die.

FIG. 6B illustrates a cross section of a spacer die in a die stack in which a pre-loaded connection pin contacts a connection pad on a thin die in which the connection pad is above a portion of the spacer die, in accordance with an embodiment of the present invention.

FIG. 7 illustrates a plan view of a spacer die in a “lattice” configuration, in accordance with an embodiment of the invention.

FIG. 8 illustrates a perspective view of a spacer die having a ventilation channel, in accordance with an embodiment of the invention.

FIG. 9 is a flowchart depicting process steps to form a die stack, in accordance with an embodiment of the present invention.

### DETAILED DESCRIPTION

C4 interconnection techniques can be used to create high-density stacked-die packages typically that include multiple silicon dies in a stacked configuration. The C4 solder bumps are tiny metallic “balls” that typically electrically connect the contact pads on two dies. Each die may include multiple electrical components and devices, and multiple device layers, and may include multiple internal interconnect layers and structures, including, for example, layer-to-layer vias. Each die may include a complete system or sub-system, or multiple interconnected dies may be required for a complete system or sub-system. To interconnect two dies, a wire is typically patterned on or in a first die that connects to a contact pad. On a second die, a corresponding contact pad is formed. On one or the other contact pads, a C4 bump is formed, the two dies are aligned within, for example, a compression bonder, and the two dies are cold-welded at the C4 bump. The C4 bumps are typically made from a solder, such as a leaded solder, e.g. Pb—Sn, a lead-free solder, e.g. SAC, or a low temperature alloy for cryogenic use, e.g., Indium.

In chip packages formed with C4 techniques, the C4 solder balls are typically relied upon not only to provide the electrical connectivity between the dies of a die stack, but also to provide mechanical rigidity during processing and use for those cases where, for example, an epoxy underfill of the C4 bumps may not be feasible due to electrical or rework limitations.

During processing and use, the C4 bumps may experience compressive, shear, twist, and other forces. These forces might include, for example, cold-weld compression forces during fabrication, preload spring biasing forces from heat sinks and connectors, torque, twist, and compression forces during manual handling of the chip stacks, etc.

Under the influence of these forces, C4 bumps may tend to “flatten” and/or “smear,” collectively referred to herein as “creep.” Further, common situations and conditions may exacerbate C4 creep. For example, creep can increase if C4 bumps subject to these forces are exposed to elevated processing or operating temperatures, or if the solder is rather soft at room temperature, such as Indium.

C4 bump creep can be detrimental to the integrity of the package. For example, as the height of a C4 bump decreases with time, its diameter increases, which may lead to electrical shorting between adjacent bumps and other connections. A decrease in bump height will also cause changes to the die stack geometry. Depending on the particular device being fabricated, this change in geometry may cause unexpected changes in the device performance, such as a change in high frequency electrical characteristics. The decrease in bump height may also cause a reduction to the preload biasing force of connector contact pins, which may cause an unexpected change in contact resistance. It would therefore be advantageous to control bump creep in a C4 die stack package.

Embodiments of the invention are directed generally to a system that controls and limits C4 bump creep. The system may also provide structural support to a die stack that might otherwise be provided by the C4 bumps in the die stack package. In various embodiments, a separate rigid spacer die having holes at the corresponding C4 bump locations is interposed between two “chip dies” that will be joined. As used herein, the term “chip die” will refer to prior art device or interposer dies that can be joined to form a die stack. The spacer die thickness corresponds to a minimum defined spacing between chip dies that is sufficient to allow for the chip dies on either side of the spacer die to, in fact, be joined with a C4 bump bonding process, and in accordance with other considerations as described below. The spacer die thickness is also dimensioned to provide a hard stop to any bump compression beyond a minimum bump height. That is, the die stack can compress until the gap between the chip dies and the spacer dies is closed, subject to, for example, surface debris and other extraneous material on the opposing surfaces. At this point, the spacer dies are providing at least compressive structural integrity to the die stack, and further C4 bump compression should not occur. The spacer dies constrain the creep of the solder in the C4 bumps in a manner that will not compromise the electrical or mechanical performance of the device without requiring the typical underfill. In certain embodiments, the spacer die may also provide structural integrity to the die stack against other stress forces, such as shear forces, through, for example, contact friction and other surface effects between the spacer die and the adjacent chip dies, and the use of close-tolerance alignment pins. When fully compressed, the spacer dies may also provide a heat bridge to conduct heat away from hot spots on a die.

In various embodiments, the spacer die may be patterned to include “lattice”-like structures, etched “pockets”, etched “channels” and other forms to allow the spacer die to be interposed between two chip dies with minimal or no modifications to the chip dies.

For the sake of brevity, conventional techniques related to semiconductor and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture circuit material structures may be well known and so, in the interest of brevity, many conventional steps may only be mentioned briefly or may be omitted entirely without providing the well-known process details.

For the clarity of the description, and without implying any limitation thereto, illustrative embodiments may be described using simplified diagrams. In an actual fabrication, additional structures that are not shown or described herein, or structures different from those shown and described herein, may be present without departing from the scope of the illustrative embodiments.

Differently patterned portions in the drawings of the example structures, layers, and formations are intended to represent different structures, layers, materials, and formations in the example fabrication, as described herein. A specific shape, location, position, or dimension of a shape depicted herein is not intended to be limiting on the illustrative embodiments unless such a characteristic is expressly described as a feature of an embodiment. The shape, location, position, dimension, or some combination thereof, are chosen only for the clarity of the drawings and the description and may have been exaggerated, minimized, or otherwise changed from actual shape, location, position, or dimension that might be used in actual fabrication to achieve an objective according to the illustrative embodiments.

An embodiment when implemented in an application causes a fabrication process to perform certain steps as described herein. The steps of the fabrication process are depicted in the several figures. Unless such a characteristic is expressly described as a feature of an embodiment, not all steps may be necessary in a particular fabrication process; some fabrication processes may implement the steps in different order, combine certain steps, remove or replace certain steps, or perform some combination of these and other manipulations of steps, without departing the scope of the illustrative embodiments.

The illustrative embodiments are described with respect to certain types of materials, electrical properties, structures, formations, layers orientations, directions, steps, operations, planes, dimensions, numerosity, data processing systems, environments, and components. Unless such a characteristic is expressly described as a feature of an embodiment, any specific descriptions of these and other similar artifacts are not intended to be limiting to the invention; any suitable manifestation of these and other similar artifacts can be selected within the scope of the illustrative embodiments.

The illustrative embodiments are described using specific designs, architectures, layouts, schematics, and tools only as examples and are not limiting to the illustrative embodiments. The illustrative embodiments may be used in conjunction with other comparable or similarly purposed designs, architectures, layouts, schematics, and tools.

The examples in this disclosure are used only for the clarity of the description and are not limiting to the illustrative embodiments. Any advantages listed herein are only examples and are not intended to be limiting to the illustrative embodiments. Additional or different advantages may be realized by specific illustrative embodiments. Furthermore, a particular illustrative embodiment may have some, all, or none of the advantages listed herein.

For purposes of the description, the terms “upper”, “lower”, “right”, “left”, “vertical”, “horizontal”, “top”, “bottom”, “outer”, “inner”, and derivatives thereof relate to the disclosed structures and methods, as oriented in the drawing figures. The terms “overlying”, “atop”, “on top”, “positioned on” or “positioned atop” mean that a first element, such as a first structure, is present on a second element, such as a second structure, and intervening elements, such as an interface structure may be present between the first element and the second element. The term “direct contact”, “directly on top of”, or the like, means that a first element, such as a first structure, and a second element, such as a second structure, are in direct contact without any intermediary conducting, insulating or semiconductor layers at the interface of the two elements.

As used herein, the term “same” when used for comparing values of a measurement, characteristic, parameter, etc., such as “the same width,” means nominally identical, such as within industry accepted tolerances for the measurement, characteristic, parameter, etc., unless the context indicates a different meaning. As used herein, the terms “about,” “approximately,” or similar terms, when used to modify physical or temporal values, such as length, time, temperature, quantity, electrical characteristics, etc., or when such values are stated without such modifiers, means nominally equal to the specified value in recognition of variations to the values that can occur during typical handling, processing, and measurement procedures. These terms are intended to include the degree of error associated with measurement of the physical or temporal value based upon the equipment available at the time of filing the application. For example, the term “about” or similar can include a range of ±8% or 5%, or 2% of a given value. In one aspect, the term “about” or similar means within 10% of the specified numerical value. In another aspect, the term “about” or similar means within 5% of the specified numerical value. Yet, in another aspect, the term “about” or similar means within 10, 9, 8, 7, 6, 5, 4, 3, 2, or 1% of the specified numerical value. In another aspect, these terms mean within industry accepted tolerances.

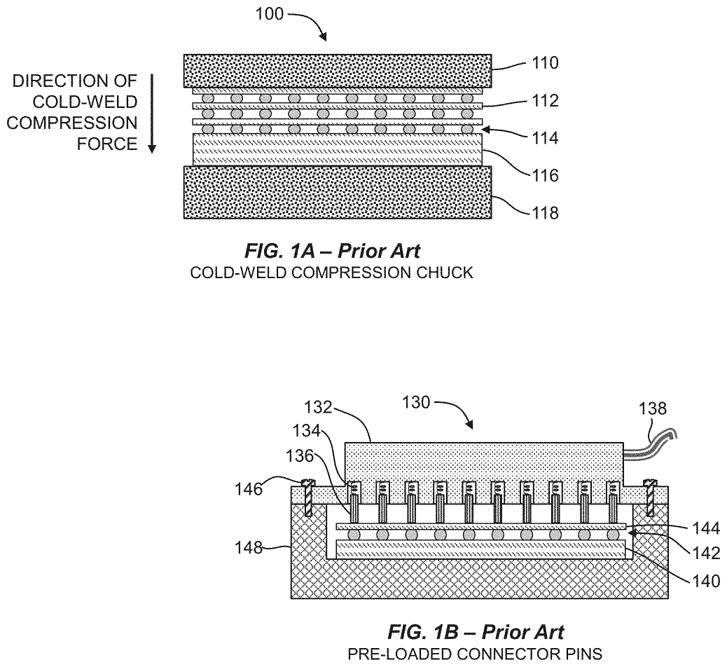

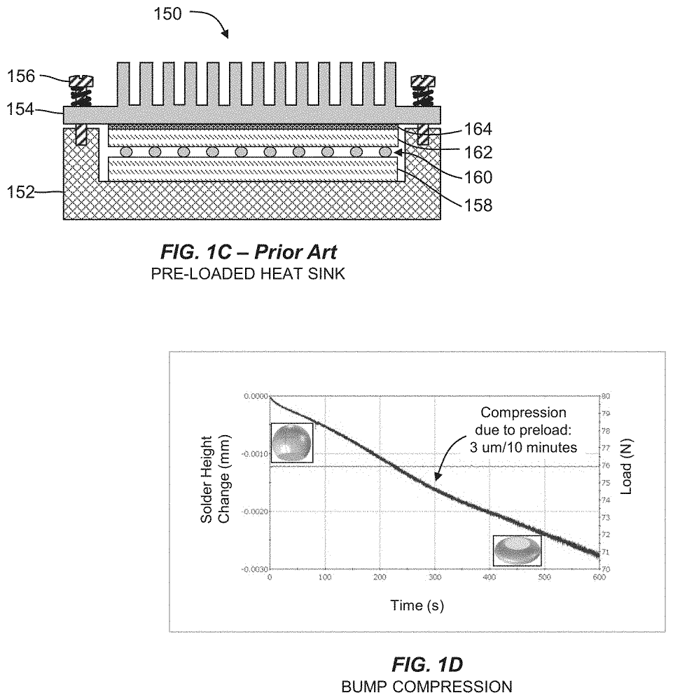

FIGS. 1A, 1B, and 1C illustrate various conditions in which C4 bumps in a die stack package can experience compressive forces that may tend to cause C4 bump creep.

FIG. 1A is a cross-section 100 of a prior art C4 die stack in a cold-weld compression process. For illustrative purposes, the die stack includes a plurality of chip dies 112 and 116, with arrays of C4 bumps 114 between the chip dies. The die stack is shown within a cold-weld compression bonding chuck having a compression bonder base plate 118 and a compression bonder pressure plate 110.

Typically, each chip die 112 is successively bonded to the chip die below it. Thus, when an “upper” chip die is bonded onto the chip die beneath, the compressive force is transmitted down the die stack to the lower C4 bump arrays 114. Each C4 bump array 114 will therefore experience the compressive bonding forces of all subsequent cold-weld compression operations for each C4 bump array 114 higher in the stack. These successive cold-weld compressions may cause an undesirable level of C4 bump creep in one or more of the lower C4 bump arrays 114.

In a multi-die stack as illustrated, the use of an underfill, if allowed by electrical and reworkability constraints, might be impractical because dispensing and curing of the underfill at every stage of a cold-weld die connection process could potentially cause contamination of the upper surface of the top chip die where the next chip die is to be attached.

FIG. 1B is a cross-section 130 of a prior art C4 die stack with a multi-channel connector that includes spring-loaded connector pins. Chip dies 140 and 144 of the die stack are joined by a C4 bump array 114. The die stack is enclosed in a housing 148. A connector handle 132 is attached to housing 148 by screws 146. The connector handle 132 includes connector pins 136 that are biased by springs 134 into contact with contact pads (not shown) on the upper chip die 144. In this example, the C4 bumps 142 take directly the compression forces imparted by the contact pin biasing springs 134. In this configuration, the bumps may experience creep due to the compression forces. As mentioned above, a decrease in bump height may also cause a reduction to the preload biasing force of the connector contact pins, which may cause an unexpected change in contact resistance.

FIG. 1C is a cross-section 150 of a prior art die stack with a pre-loaded heat sink. A die stack comprising chip dies 158 and 162 are joined by a C4 bump array 160. The die stack is in a housing 152. A heat sink 154 is in thermally conductive contact with the die stack through a thermal interface material layer 164. To optimize the heat transfer from the die stack to the heat sink 154 and minimize the thickness of the thermal interface material layer 164, the heat sink is spring biased against the thermal interface material layer by spring-loaded screws 156. In this example, an underfill surrounding the C4 bumps 160 is not used, and the C4 bumps take directly the compression forces imparted by the spring-loaded screws 156. In this configuration, the bumps may experience creep due to the compression forces. The decrease in bump height may cause a reduction to the preload biasing force of the spring-loaded screws 156, which may cause an unexpected change in the heat transfer characteristics of the system. Even a “hard” solder, such as SAC, when used in a high temperature environment may also undergo creep.

FIG. 1D is a plot illustrating experimental results for C4 bump deformation over time as a function of a compression load. The plot shows the room temperature behavior of ˜500 Indium C4 bumps, each about 75 μm high, when exposed to a 15 gm/C4 bump compressive force. This is the typical load applied by each contact pin of the connector. As illustrated, the C4 bumps creep at a continuous rate of about 3 μm per 10-minute interval. Creep in Indium has been extensively studied and found to occur even at cryogenic temperatures.

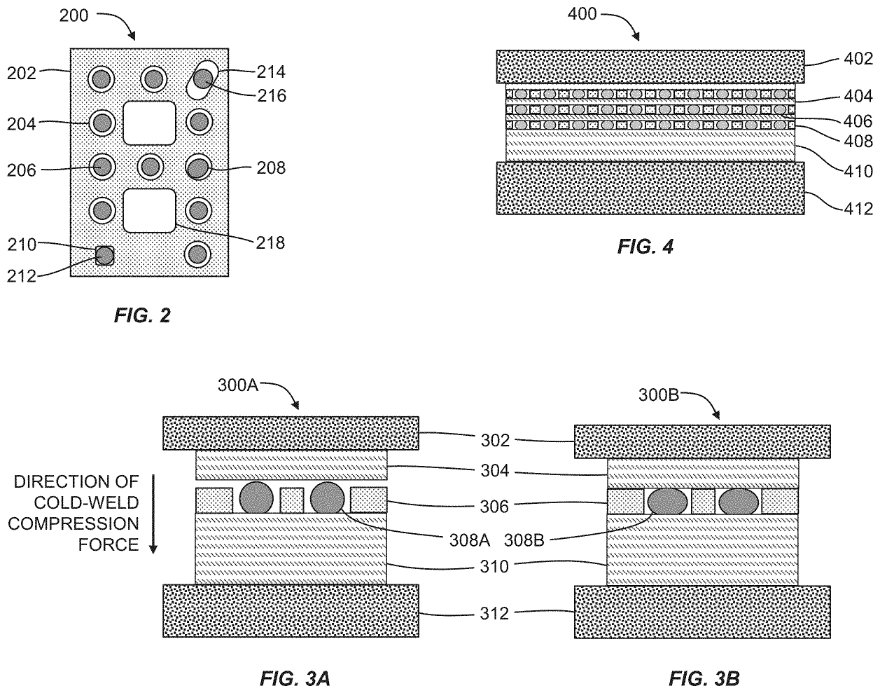

FIG. 2 illustrates a plan view 200 of a spacer die 202, in accordance with an embodiment of the invention. In an exemplary embodiment, spacer die 202 includes through-holes 204 dimensioned to accommodate C4 bumps 206. In use, the spacer die is aligned and placed over a lower chip die such that the through-holes 204 of the spacer die 202 go around the C4 bumps 206, or the contact pads where they attach (not shown). An upper chip die is then aligned and placed on the top of the spacer die 202. The die stack, including the sandwiched spacer die 202, may then be compression bonded or sent through a reflow oven to achieve the final assembled die stack. The die stack assembly process can be extended by aligning an additional spacer die onto the top chip die of the stack, aligning an additional “upper” chip die onto the spacer die, and bonding the newly added upper chip die to the die stack.

In certain situations, maintaining the alignment of the spacer die with respect to chip dies just above and just below the spacer die may be desirable. For example, if the process calls for the solder for the C4 bumps to be injected onto the contact pads of a chip die after alignment and placement of the spacer die, some mechanism to hold the spacer die in alignment on the chip die would be desirable. In other situations, the die stack may experience shear forces tending the smear the C4 bumps. Here, some mechanism to maintain structural integrity of the die stack against such shear forces would be desirable beyond, for example, what might be provided by surface friction and other surface effects between the spacer die and adjacent chip dies.

FIG. 2 illustrates alignment holes 210 and 214 which engage corresponding alignment pins 212 and 216 from a chip die. As illustrated, alignment pin 212 fits alignment hole 210 with a close tolerance. In certain embodiments, alignment pin 212 may be inserted into alignment hole 210 in a “compression fit” arrangement. Alignment hole 214 is illustrated as elongated in an oblong shape to allow for a measure of thermal expansion mismatch, resulting in differential movement, between the spacer die 202 and the chip die to which alignment pin 216 is attached. Generally, alignment pins 212 and 216 are attached to the chip die below spacer die 202 to hold the spacer die in alignment during the bonding process. However, the alignment pins can be attached to the chip die above the spacer die, or to the chip die above and the chip die below the spacer die. This last arrangement may be advantageous to limit lateral movement in the chip stack die due to shear forces on the stack. In certain embodiments, alignment pins can be attached to spacer die 202 and fit into alignment holes located on one or both of the chip dies between which the spacer die is interposed.

In various embodiments, the holes in the spacer dies have a diameter that is large enough to not make contact with the C4 bumps after the die stack is compressed to the maximum amount allowed by the height of the interposed spacer dies, and the C4 bump diameters have increased to their maximum amount due to their compression. Further, the volume of the holes in the spacer dies is larger than the volume of the C4 bump. This may be advantageous, for example, because changes to the fabrication process of record may be minimized with the exception of interposing the spacer dies between chip dies to be joined. Also, dimensioning the diameter of the holes in the spacer dies to be larger than the expected maximum bump diameter, and the volume of the holes to be larger than the C4 bumps, may help to ensure that there is no “overflow” out of the holes in the spacer dies of the C4 bumps after maximum compression.

As mentioned, it may be advantageous to dimension the through-holes 204 in spacer die 202 such that after an expected amount of symmetric radial expansion of the bumps resulting from an expected maximum amount of creep, the bumps do not contact the sidewalls of the through-holes 204. However, if bump creep does occur in an asymmetric manner, as illustrated by smeared bump 208, the creep is constrained within the through-holes 204.

FIG. 2 also illustrates device holes 218 in spacer die 202. Such device holes may be advantageous to keep the spacer die away from devices on the chip die surfaces facing the spacer die. This would be advantageous for reducing any electrical effects the spacer die material may have on the devices on the chip die surfaces, and to reduce any mechanical interference of the spacer die with a device on the chip die surfaces facing the spacer die.

FIGS. 3A and 3B illustrate cross sections 300A and 300B, respectively, of a spacer die 306 in a die stack before and after a cold-weld compression process step, in accordance with an embodiment of the invention. As illustrated in FIG. 300A, chip die 310 includes C4 bumps 308A. Spacer die 306 is aligned and placed on top of chip die 310 such that C4 bumps 308A are within the holes of the spacer die. Chip die 304 is aligned with chip die 310 in anticipation of a bonding operation, and chip dies 304 and 310 and spacer die 306 are held between compression bonder base plate 312 and compression bonder pressure plate 302.

FIG. 3B illustrates the result of a compression bonding operation upon the die stack. As illustrated, chip dies 304 and 310 are connected by compressed C4 bump bonds 308B. Spacer die 306 has limited the compression of C4 bumps 308B to the thickness of the spacer die while allowing the compression bonding to be successfully performed. Any subsequent compression bonding operations on the die stack will not result in additional compression of C4 bumps 308B as spacer die 306 acts as a hard stop against such additional compression.

FIG. 4 illustrates a cross section 400 of a die stack that has undergone a compression bonding operation in which the die stack includes a plurality of chip and spacer dies, in accordance with an embodiment of the invention. As illustrated, a die stack comprising a chip die 410 and a multiplicity of chip dies 404 have been joined at C4 bumps 406 in successive compression bonding operations, via a compression bonder base plate 412 and a compression bonder pressure plate 402. A spacer die 408 is interposed between each pair of adjacent chip dies 404 and acts as a hard stop against further compression of the die stack beyond what is required to successfully perform each compression bonding operation.

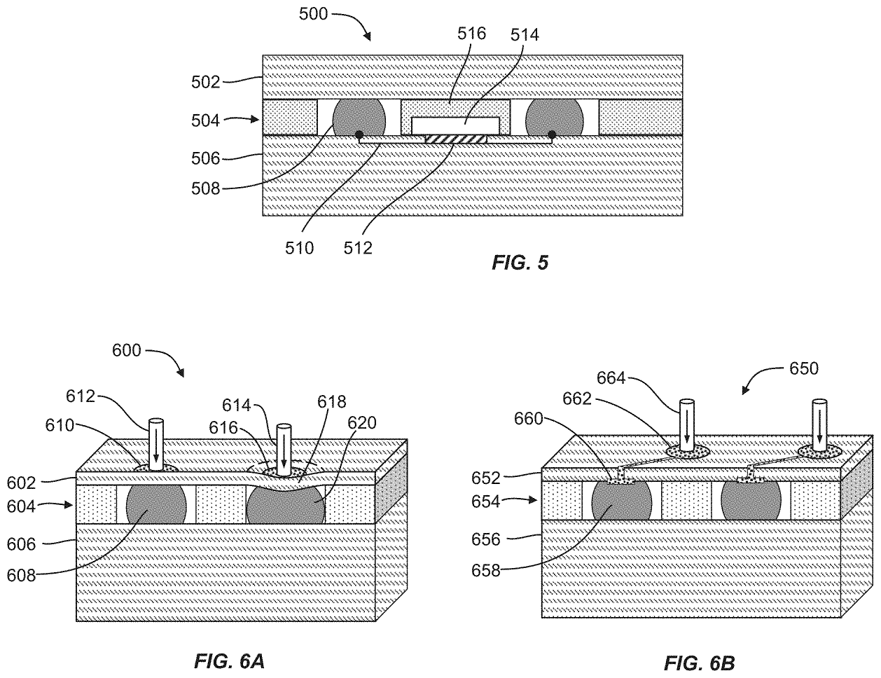

FIG. 5 illustrates a cross section of a die stack 500 that includes a spacer die 504 in which the spacer die includes an etched pocket 514 over a device 512, in accordance with an embodiment of the invention. As illustrated, a die stack comprising chip dies 502 and 506 are joined at C4 bumps 508 as the result of a compression bonding operation. Chip die 506 includes a device 512 on its surface. For illustrative purposes, device 512 has metal layer connections 510 to both C4 bumps 508. Spacer die 504 has been interposed between chip dies 502 and 506 prior to the compression bonding process, and will act as a hard stop against further compression of C4 bumps 508. In this embodiment, to mitigate electrical and/or mechanical interference between the spacer die 504 and the surface device 512, a pocket 514 has been formed in the spacer die to remove material near the surface device. This is an alternative embodiment to the device through-hole 218 of FIG. 2 and may be advantageous when structural support provided by the spacer die is desired at the surface device 512.

FIG. 6A illustrates a cross section 600 of a die stack in which a pre-loaded contact pin 614 contacts a connection pad 616 on a thin chip die 602 and causes a deformation 618 to the thin die and the bump 620 underneath the thin chip die. As shown, a die stack comprising chip dies 602 and 606 are joined at C4 bumps 608 and 620 by a compression bonding process. A spacer die 604 is interposed between chip dies 602 and 608 for the purpose of limiting further creep of the bump bonds that join the two chip dies. A shown, a first spring-loaded contact pin 612 makes contact to a contact pad 610 connected to C4 bump 608. However, the bias force of a second spring-loaded contact pin 614 is large enough to cause a deformation 618 in the chip die 602 at the point of contact on the contact pad 616, which causes a deformation to C4 bump 620.

FIG. 6B illustrates a cross section 650 of a die stack in which a pre-loaded connection pin 664 contacts a connection pad 662 on a thin chip die 652 in which the connection pad 662 is located above a portion of a spacer die 654, in accordance with an embodiment of the present invention. In this arrangement, the spacer die 654 provides compressive structural support to the thin chip die 652 at the point where the pre-loaded connection pin 664 contacts the connection pad 662 on the thin chip die 652. As illustrated, chip dies 656 and 652 of a die stack are joined at C4 bumps 658. A spacer die 654 is interposed between chip dies 656 and 652 to provide structural support to the die stack against compressive and other forces.

A contact pad 660, to which C4 bump 658 is welded, is connected to another contact pad 662 on the surface of the die stack that is offset from contact pad 660. Contact pad 662 is positioned on chip die 652 such that it is above a portion of spacer die 654. When pre-loaded contact pin 664 makes contact with contact pad 662, the portion of spacer die 654 below contact pad provides compressive structural support to thin chip die 652 so as to prevent the deformation 618 shown in FIG. 6A.

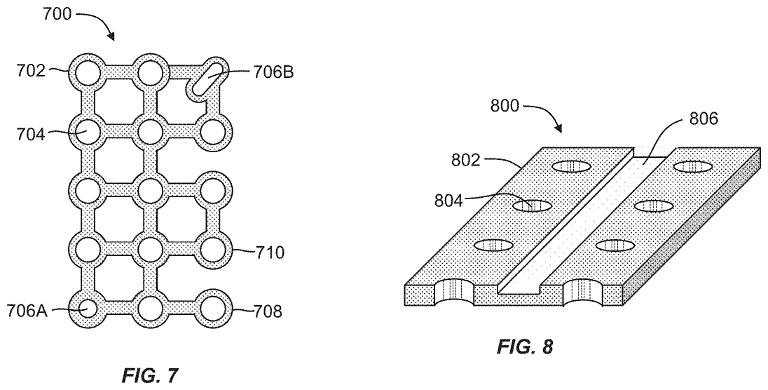

FIG. 7 illustrates a plan view 700 of a spacer die 702 having a “lattice” configuration, in accordance with an embodiment of the invention. Here, a significant amount of material has been removed from spacer die 702 while still including through holes 704 to surround C4 bumps, and, as illustrated, still including alignment holes 706A and 706B. While the configuration is shown as a “regular” lattice, irregular shapes are also contemplated. Also, a through-hole structure may be connected to another through-hole by only a single “vertex”, such as through-hole structure 708, two vertices, such as through-hole structure 710, or more vertices.

FIG. 8 illustrates a perspective view 800 of a spacer die 802 that includes a channel 806 in addition to through-holes 804, in accordance with an embodiment of the invention. The channel 806 may be used, for example, to accommodate devices or other structures at the surface of a chip die, and/or to allow for airflow through the die stack.

While various aspects and configurations of a spacer die have been illustrated in separate embodiments, combinations of these may be implemented as desired and as may be required for a particular die stack.

Because a primary purpose of the spacer die is to provide a “hard” stop against compressive forces in a die stack, and also to mitigate bump creep from other forces, such as shear, torque, and twist, the spacer die should be formed from a material having sufficient rigidity along the different axes to limit creep to the desired degree. It may be advantageous if the coefficient of thermal expansion (CTE) of the spacer die material matches or is similar enough or is within a defined tolerance of the CTE of the chip dies so as to avoid damage to bumps caused by an expansion mismatch.

In various embodiments, the spacer die may be formed from the same material as the chip dies in the die stack, or from a non-conducting material with sufficient rigidity and with a CTE that matches or is within a defined tolerance of the CTE of the chip dies. Examples of such materials include silicon and glass. For microwave frequency applications, the use of a low dielectric material such as silicon may be desirable to minimize electrical loss in the circuits.

As described above, the spacer dies may be formed separately from the chip dies, and are aligned and placed on a first chip die before a second chip is joined to the first chip die via a C4 bump bonding process.

The through-holes in a spacer die may be fabricated by known techniques that are suitable to the spacer die material and the desired dimensions, such as etching the spacer material either by laser or chemical means, or by mechanical drilling. Similarly, the removal of material to form lattice structures, device “pockets”, and channels may be fabricated by known techniques.

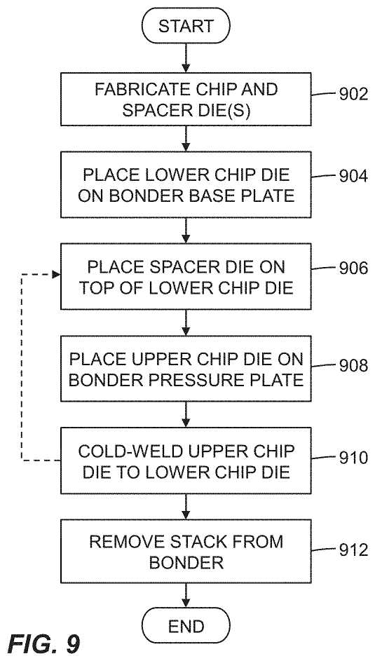

FIG. 9 is a flowchart depicting process steps for forming a die stack, in accordance with an embodiment of the invention. Two or more chip dies and at least one spacer die to be placed between the chip dies is fabricated (step 902). For example, chip dies 304 and 310, and spacer die 306 (FIG. 3) are fabricated. As described above, each spacer die is typically fabricated to accommodate surface features of the two chip dies between which the spacer die will be interposed in the completed chip stack. A “lower” chip die is placed on a bonder base plate (step 904). For example, chip die 310 is placed on bonder base plate 312.

A spacer die is placed on top of the lower chip die (step 906). For example, spacer die 306 is placed on top of lower chip die 310. As described above, the spacer die is aligned with the lower chip die before placement. In certain embodiments, this alignment is assisted by the use of alignment pins and alignment holes. See, for example, alignment pins 212 and 216, and associated alignment holes 210 and 214, described above with reference to FIG. 2.

An upper chip die is placed on the bonder pressure plate (step 908). For example, chip die 304 is placed on bonder compression plate 302. The upper chip die is then cold-welded to the lower die by a compression welding process (step 910). For example, a compression force is applied to bonder compression plate 302 to cold-weld upper chip die 304 to lower chip die 310 at C4 bumps 308.

Optionally, if the chip stack includes additional chip dies, such as illustrated in FIG. 4, steps 906, 908, and 910 can be repeated until all chip dies in the chip stack have been cold-welded. After the chip stack is complete, the stack is removed from the bonder (step 912), and the process is complete.

Based on the foregoing, a structure and a method have been disclosed. However, numerous modifications and substitutions can be made without deviating from the scope of the present invention. Therefore, the present invention has been disclosed by way of example and not limitation.

What is claimed is:

1. A die stack, comprising:
a first chip die;
a second chip die connected to the first chip die by one or more controlled collapse chip connection (“C4”) solder bump bonds; and
a spacer die interposed between the first and second chip dies;
wherein:
the spacer die includes through holes for the one or more C4 solder bumps;
the spacer die has a thickness such that when the first and second chip dies are compressed into contact with the spacer die, the spacer die thickness has a minimum defined spacing between the first and second chip dies; and
the spacer die operates as a hard stop against compression of the die stack after the first and second chip dies are compressed into contact with the spacer die.

2. A die stack in accordance with claim 1, wherein an alignment hole through the spacer die engages a corresponding alignment pin on one of the first chip die or the second chip die, or engages alignment pins on both of the first chip die and the second die.

3. A die stack in accordance with claim 1, wherein an alignment pin on the spacer die engages a corresponding alignment hole on one of the first or second chip dies.

4. A die stack in accordance with claim 1, wherein an alignment hole through the spacer die engages a corresponding alignment pin on one of the first chip die or the second chip die, or engages alignment pins on both of the first and the second chip dies, and an alignment pin on the spacer die engages a corresponding alignment hole on one of the first chip die or the second chip die.

5. A die stack in accordance with claim 2, further comprising two alignment pins and corresponding two alignment holes, wherein one of the alignment holes is dimensioned to fit its corresponding alignment pin to a close tolerance, and the other alignment hole is dimensioned with a sufficient oblong shape to allow for differential movement between the spacer die and one or both chip dies as a result of a difference between the coefficient of thermal expansion (CTE) of the spacer die and the chip dies.

6. A die stack in accordance with claim 1, wherein the spacer die further comprises one or both of:
a device through hole aligned with a device on one of the first chip die or the second chip die, to reduce one or both of mechanical interference of the spacer die on the device or electrical effects of the spacer die on the device; and
a device pocket etched into the spacer die that is aligned with a device on one of the first chip die or the second chip die, to reduce one or both of mechanical interference of the spacer die on the device, or electrical effects of the spacer die on the device.

7. A die stack in accordance with claim 1, wherein the spacer die further comprises a channel etched into the spacer die that accommodates airflow through the die stack.

8. A die stack in accordance with claim 1, wherein the spacer die comprises a lattice configuration.

9. A die stack in accordance with claim 1, wherein one of the first chip die and the second chip die includes a pre-loaded connection pin contact pad aligned with a portion of the spacer die that provides compressive structural support to the chip die at the point where the pre-loaded connection pin contacts the connection pad.

10. A die stack in accordance with claim 1, wherein the spacer die thickness allows for cold-weld compression bonding of the first chip die to the second chip die.

11. A die stack in accordance with claim 1, wherein the diameter of each through hole is sufficiently larger than its corresponding uncompressed C4 bump such that an aligned spacer die may be placed on its associated chip die without touching any of the uncompressed C4 bumps.

12. A die stack in accordance with claim 1, wherein the dimensions of each through hole are such that when the first chip die and second chip die are compressed into contact with the spacer die, the volume of the through hole is greater than the volume of its corresponding C4 bump such that the C4 bump does not overflow the through hole, and expansion of the C4 bump diameter does not cause electrical shorting between adjacent bumps or other connections.

13. A die stack in accordance with claim 1, wherein the spacer die is comprised of the same materials as the substrate materials of the first and second chip dies.

14. A die stack in accordance with claim 1, wherein the spacer die is comprised of a non-conducting material that acts as a hard stop against compression of the die stack after the first and second chip dies are compressed into contact with the spacer die, and with a coefficient of thermal expansion (CTE) similar enough to the CTE of the chip dies so as to eliminate damage to the C4 bumps caused by differential movement between the spacer die and one or both chip dies as a result of a difference between the CTEs of the spacer die and the chip dies.

15. A die stack in accordance with claim 1, wherein the spacer die is comprised a material selected from the group consisting of silicon, and glass.

16. A method of forming a die stack, comprising:
fabricating a first chip die, a second chip die, and a spacer die.
placing the first chip die on a bonder base plate;
placing the spacer die on top of the first chip die;
placing the second chip die on a bonder pressure plate; and
cold-welding the first chip die to the second chip die, at one or more controlled collapse chip connection (“C4”) solder bump bonds on one or both of the first chip die and the second chip die, by applying a compression force to the bonder compression plate;
wherein:
the spacer die includes through holes for the one or more C4 solder bumps;
the spacer die has a thickness such that when the first and second chip dies are compressed into contact with the spacer die, the spacer die thickness is a minimum defined spacing between the first and second chip dies; and
the spacer die operates as a hard stop against compression of the die stack after the first and second chip dies are compressed into contact with the spacer die.

17. A method in accordance with claim 16, wherein the first chip die, second chip die, and spacer die are fabricated such that an alignment hole through the spacer die engages a corresponding alignment pin on one of the first chip die or the second chip die, or engages alignment pins on both of the first chip die and the second die.

18. A method in accordance with claim 16, wherein the first chip die, second chip die, and spacer die are fabricated such that an alignment pin on the spacer die engages a corresponding alignment hole on one of the first chip die or the second chip die.

19. A method in accordance with claim 16, wherein the first chip die, second chip die, and spacer die are fabricated such that an alignment hole through the spacer die engages a corresponding alignment pin on one of the first chip die or the second chip die, or engages alignment pins on both of the first chip die and the second die, and an alignment pin on the spacer die that engages a corresponding alignment hole on one of the first chip die or the second chip die.

20. A method in accordance with claim 17, further comprising two alignment pins and a corresponding two alignment holes, wherein one of the alignment holes is dimensioned to fit its corresponding alignment pin to a close tolerance, and the other alignment hole is dimensioned with a sufficient oblong shape to allow for differential movement between the spacer die and one or both chip dies caused by a difference between the coefficient of thermal expansion (CTE) of the spacer die and the chip dies.

21. A method in accordance with claim 16, wherein the spacer die is fabricated to comprise a device through hole aligned with a device on one of the first or the second chip dies, so as to reduce mechanical interference and/or electrical effects of the spacer die on the device.

22. A method in accordance with claim 16, wherein the spacer die is fabricated to comprise a device pocket etched into the spacer die and aligned with a device on one of the first chip die or the second chip die, so as to reduce one or both of mechanical interference of the spacer die on the device, or electrical effects of the spacer die on the device.

23. A method in accordance with claim 16, wherein the spacer die is fabricated to comprise a channel etched into the spacer die to accommodate airflow through the die stack.

24. A method in accordance with claim 16, wherein the spacer is fabricated in a lattice configuration.

25. A method in accordance with claim 16, wherein one of the first chip die and the second chip die is fabricated to include a pre-loaded connection pin contact pad aligned with a portion of the spacer die that provides compressive structural support to the chip die at the point where the pre-loaded connection pin contacts the connection pad.

26. A method in accordance with claim 16, wherein the spacer die is fabricated such that the spacer die thickness allows for cold-weld compression bonding of the first chip die to the second chip die.

27. A method in accordance with claim 16, wherein the spacer die is fabricated such that the diameter of each through hole is sufficiently larger than its corresponding uncompressed C4 bump such that a properly aligned spacer die can be placed on its associated chip die without touching the uncompressed C4 bumps.

28. A method in accordance with claim 16, wherein the spacer die is fabricated such that the dimensions of each through hole are such that when the first and second chip dies are compressed into contact with the spacer die, the volume of the through hole is greater than the volume of its corresponding C4 bump such that the C4 bump does not overflow the through hole, and expansion of the C4 bump diameter does not cause electrical shorting between adjacent bumps and other connections.

29. A method in accordance with claim 16, wherein the spacer die is fabricated of the same materials as the substrate materials of the first and second chip dies.

30. A method in accordance with claim 16, wherein the spacer die is fabricated of a non-conducting material that acts as a hard stop against compression of the die stack after the first chip die and the second chip die are compressed into contact with the spacer die, and with a coefficient of thermal expansion (CTE) similar enough to the CTE of the chip dies so as to eliminate damage to the C4 bumps caused by a differential movement between the spacer die and one or both chip dies as a result of a difference between the CTEs of the spacer die and the chip dies.

31. A method in accordance with claim 16, wherein the spacer die is fabricated of a material selected from the group consisting of silicon, and glass.
